(19) United States
(12) Patent Application Publication
(10) Pub. No.: US 2026/0052925 A1
(43) Pub. Date: Feb. 19, 2026

(54) GRINDING METHOD FOR SEMICONDUCTOR STRUCTURE

(71) Applicant: United Microelectronics Corp., Hsinchu (TW)

(72) Inventors: Chi-Wen CHEN, Kaohsiung City (TW); Ang CHAN, Taipei City (TW); Hsin-Jung LIU, Pingtung County (TW); Chau-Chung HOU, Kaohsiung City (TW)

(21) Appl. No.: 18/896,996

(22) Filed: Sep. 26, 2024

(30) Foreign Application Priority Data
Aug. 15, 2024 (TW) 113130667

(51) Int. Cl. H01L 21/304; H01L 23/00

(52) U.S. Cl. CPC H01L 21/304; H01L 24/80; H01L 2224/80895; H01L 2224/80896

(57) ABSTRACT

A grinding method includes the following steps. Firstly, a dressing layer is formed on a semiconductor structure. Then, a grinding tool grinds the dressing layer and semiconductor structure.

This application claims priority of Taiwan application Serial No. 113130667, filed Aug. 15, 2024, the subject matter of which is incorporated herein by reference.

### BACKGROUND

### Technical Field

The disclosure relates to a grinding method for a semiconductor structure.

### Description of Background

Based on demand, a semiconductor structure is usually ground with a grinding tool. However, the grinding tool will wear due to grinding a metal layer in the semiconductor structure, resulting in an appearance deviation (unevenness) of the grinding tool. The uneven grinding tool will form an uneven grinding surface on the semiconductor structure.

### SUMMARY

The present invention relates to a grinding method for a semiconductor structure, capable of improving the aforementioned conventional problems.

One aspect of the present disclosure is to provide a grinding method for a semiconductor structure. The grinding method includes steps as follows: forming a dressing layer on the semiconductor structure; and grinding the dressing layer and the semiconductor structure by a grinding tool.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1 illustrates a flow chart of a grinding method for a semiconductor wafer according to an embodiment of the present invention;

FIG. 2A illustrates a schematic diagram of the semiconductor structure according to an embodiment of the present invention;

FIG. 2B illustrates a schematic diagram of a cross-sectional view of the semiconductor structure of FIG. 1A along a direction 2B-2B′;

FIG. 3 illustrates a schematic diagram of the semiconductor structure in FIG. 2B after being thinned;

FIG. 4 illustrates a schematic diagram of the semiconductor structure of FIG. 3 in which the dressing layer is formed;

FIG. 5A illustrates a schematic diagram of the grinding tool grinding the dressing layer and the semiconductor structure;

FIGS. 5B and 5C illustrate schematic diagrams of the grinding tool in FIG. 5A and the semiconductor structure in FIG. 5B viewed from different angles;

FIG. 5D illustrates a schematic diagram of the entire of an edge area of the semiconductor structure in FIG. 5B being removed; and

FIG. 6 illustrates a schematic diagram of the dressing layer on the semiconductor structure in FIG. 5D being removed.

### DETAILED DESCRIPTION

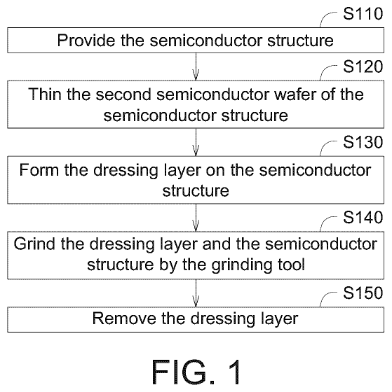

Referring to FIG. 1, FIG. 1 illustrates a flow chart of a grinding method for a semiconductor wafer according to an embodiment of the present invention.

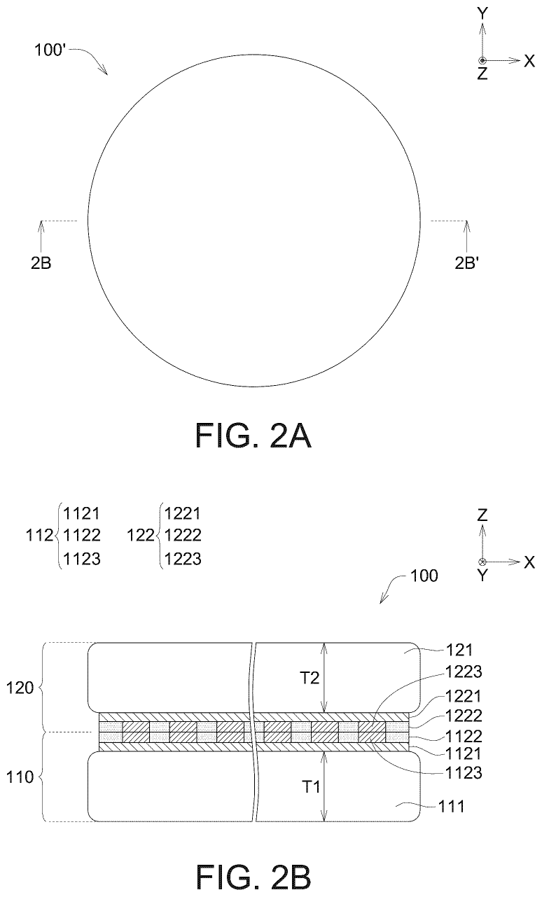

In step S110, referring to FIGS. 2A and 2B, FIG. 2A illustrates a schematic diagram of the semiconductor structure 100 according to an embodiment of the present invention, and FIG. 2B illustrates a schematic diagram of a cross-sectional view of the semiconductor structure 100 of FIG. 1A along a direction 2B-2B′. In this step, the semiconductor structure 100 is provided. The semiconductor structure 100 is, for example, a semiconductor stack structure. The semiconductor structure 100 includes a first semiconductor wafer module 110 and a second semiconductor wafer module 120 connected opposite to the first semiconductor wafer module 110.

As illustrated in FIGS. 2A and 2B, the first semiconductor wafer structure 110 includes a first semiconductor wafer 111 and a first semiconductor layer 112. The first semiconductor wafer 111 is, for example, a silicon wafer, such as a wafer that has not been singulated (not yet sawed), and its size is, for example, 8 inches, 12 inches, or other smaller or larger sizes. The first semiconductor layer 112 at least includes a circuit layer 1121, a dielectric layer 1122 and at least one pad 1123. The circuit layer 1121 is formed on the first semiconductor wafer 111. The circuit layer 1121 includes, for example, a front-end-of-line (FEOL) layer and a back-end-of-line (BEOL) layer, wherein the FEOL layer includes, for example, at least one transistor and/or at least one passive component, and the BEOL layer includes, for example, wires and/or conductive vias that are electrically connected to the FEOL layer. The dielectric layer 1122 covers the circuit layer 1121, the pads 1123 are formed in the dielectric layer 1122 and are electrically connected to the circuit layer 1121. Although not illustrated, the circuit layer 1121 further includes at least one conductive via that may be electrically connected to the pads 1123.

As illustrated in FIGS. 2A and 2B, the second semiconductor wafer structure 120 includes a second semiconductor wafer 121 and a second semiconductor layer 122. The second semiconductor wafer 121 is, for example, a silicon wafer, such as a wafer that has not been singulated (not yet sawed), and its size is, for example, 8 inches, 12 inches, or other smaller or larger sizes. The second semiconductor layer 122 at least includes a circuit layer 1221, a dielectric layer 1222 and at least one pad 1223. The circuit layer 1221 is formed in the second semiconductor wafer 121. The circuit layer 1221 is, for example, a FEOL layer and a BEOL layer. The FEOL layer may include at least one transistor and/or at least one passive component. The BEOL layer may include circuits and/or conductive vias that are electrically connected to the FEOL layer. The dielectric layer 1222 covers the circuit layer 1221. The pads 1223 are formed in the dielectric layer 1222 and are electrically connected to the circuit layer 1221. Although not illustrated, the circuit layer 1221 further includes at least one conductive via that may be electrically connected to the pad 1223.

In an embodiment, the semiconductor structure 100 may be formed using the following steps.

Firstly, the first semiconductor layer 112 is formed on the first semiconductor wafer 111, by using at least one semiconductor process (for example, deposition, lithography process, etching, etc.), to form the first semiconductor wafer module 110. Then, the second semiconductor layer 122 is formed on the second semiconductor wafer 121, by using at least one semiconductor process (for example, deposition, lithography process, etching, etc.), to form the second semiconductor wafer module 120. Then, the first semiconductor layer 112 and the second semiconductor layer 122 are connected to connect the first semiconductor wafer module 110 with the second semiconductor wafer module 120 to form the semiconductor structure 100 as illustrated in FIG. 2B, wherein the first semiconductor layer 112 and the second semiconductor layer 122 are disposed between the first semiconductor wafer 111 and the second semiconductor wafer 121. In an embodiment, the first semiconductor wafer 111 has a first original thickness T1, and the second semiconductor wafer 121 has a second original thickness T2, wherein the first original thickness T1 and/or the second original thickness T2 are, for example, about 775 micrometers (μm).

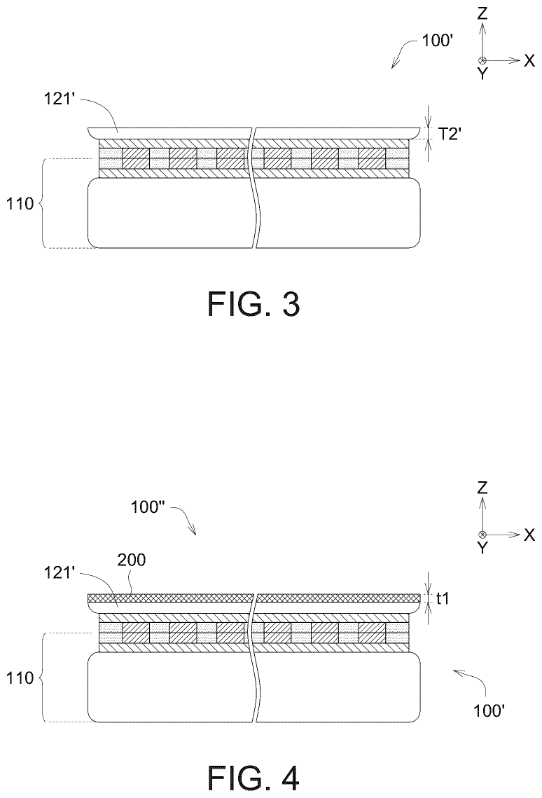

In step S120, referring to FIG. 3, FIG. 3 illustrates a schematic diagram of the semiconductor structure 100 in FIG. 2B after being thinned. In this step, the second semiconductor wafer 121 of the semiconductor structure 100 is thinned by using at least one of, for example, a grinding, a chemical-mechanical planarization (CMP) and an etching. The thinned semiconductor structure is represented by symbol 100′, and the thinned second semiconductor wafer is represented by symbol 121′. In an embodiment, the second semiconductor wafer 121′has a thinned thickness T2′which may range between 230 μm and 240 μm, for example, about 236 μm.

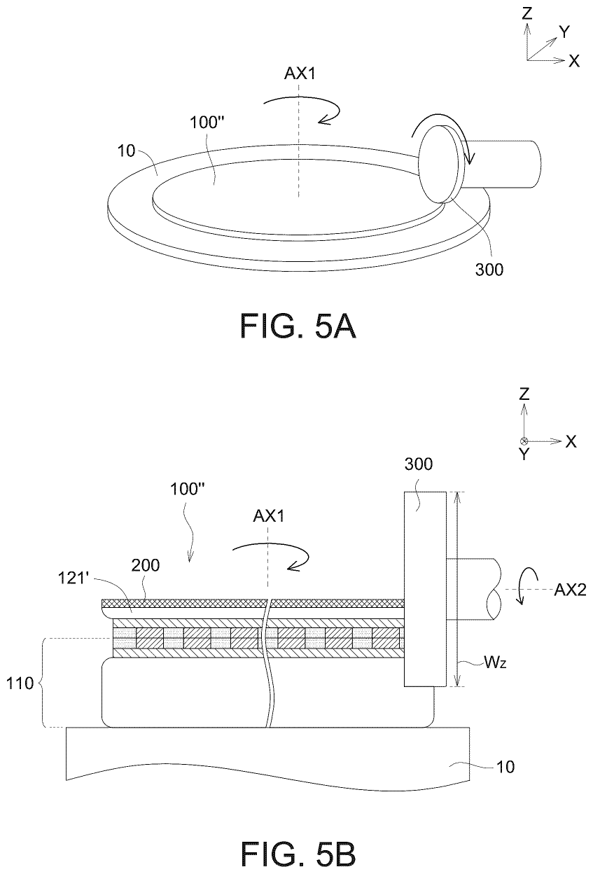

In step S130, referring to FIG. 4, FIG. 4 illustrates a schematic diagram of the semiconductor structure 100′of FIG. 3 in which the dressing layer 200 is formed. In this step, the dressing layer 200 is formed on the semiconductor structure 100′by using, for example, a deposition technique. For example, the dressing layer 200 is formed on the second semiconductor wafer 121′of the semiconductor structure 100′. The semiconductor structure with the dressing layer 200 may be represented by symbol 100″. The dressing layer 200 is, for example, a dielectric film. The dressing layer 200 is the outermost layer of the semiconductor structure 100″. The dressing layer 200 may be formed of material including oxide or nitride, wherein the oxide is, for example, aluminum oxide (Al₂O₃), etc., and the nitride is, for example, silicon nitride (Si₃N₄), etc. The dressing layer 200 has high hardness to dress (or shape) a grinding tool. In an embodiment, the dressing layer 200 has a Mohs hardness equal to or greater than 8. In addition, the dressing layer 200 has a layer thickness t1, and the layer thickness t1 may be obtained by inferring the volume of the loss amount of a dressing board (not illustrated). Furthermore, in a comparative example, the grinding tool may be dressed (or shaped) on the dressing board, so the dressing board will produce a wear loss, and the layer thickness t1 of the dressing layer 200 may be calculated based on the volume of the aforementioned wear loss. In an embodiment, the layer thickness t1 of the dressing layer 200 may range between 1 μm and 4 μm, such as 2 μm.

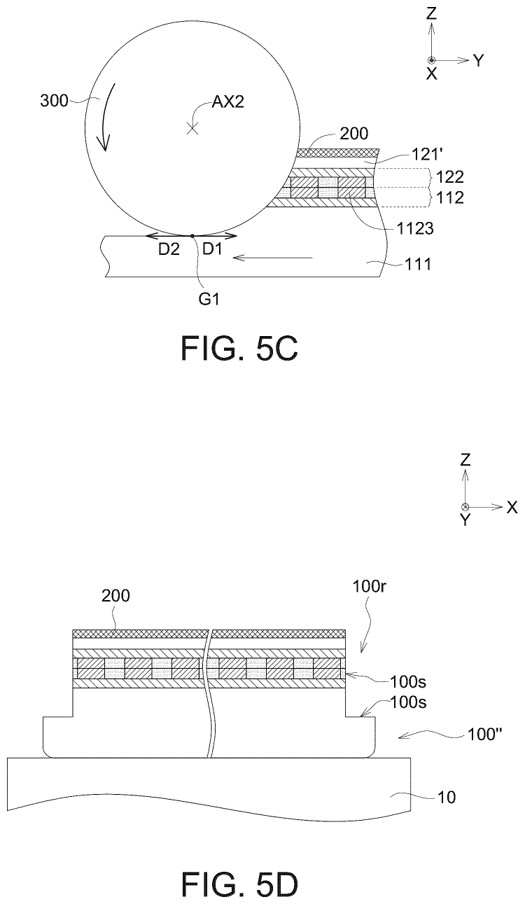

In step S140, referring to FIGS. 5A to 5D, FIG. 5A illustrates a schematic diagram of the grinding tool grinding the dressing layer and the semiconductor structure, FIGS. 5B and 5C illustrate schematic diagrams of the grinding tool 300 in FIG. 5A and the semiconductor structure 100″ in FIG. 5B viewed from different angles, and FIG. 5D illustrates a schematic diagram of the entire of an edge area of the semiconductor structure 100″ in FIG. 5B being removed (but still retain a portion of the thickness of the semiconductor structure 100″).

In this step, the semiconductor structure 100″ may be disposed on a platform 10 (for example, chunk table) first. Then, a driving device (for example, a motor) drives the platform 10 to rotate around a rotation axis AX1 to drive the semiconductor structure 100″ to synchronously rotate around the rotation axis AX1, wherein the rotation axis AX1 passes through a center of the semiconductor structure 100″ and is substantially parallel to Z-axis. When the semiconductor structure 100″ rotates, the grinding tool 300 rotates around the rotation axis AX2 to grind the edge area of the semiconductor structure 100″, wherein the rotation axis AX2 passes through a center of the grinding tool 300 and is substantially parallel to X-axis. In an embodiment, a rotation speed of the grinding tool 300 may range between 25,000 revolutions per minute (rpm) and 40,000 rpm, such as 30,000 rpm and 35,000 rpm, and a rotation speed of the platform 10 may range between, for example, 2 degrees per second (degrees/second) to 4 degrees/second. In addition, the hardness of the dressing layer 200 may be greater than the hardness of the abrasive of the grinding tool 300.

As illustrated in FIG. 5C, in the present embodiment, at a grinding point G1, a tangential direction D1 of the rotation of the semiconductor structure 100″ is opposite to a tangential direction D2 of the rotation of the grinding tool 300. As a result, during the grinding process, the grinding tool 300 sequentially grinds the first semiconductor wafer 111, the first semiconductor layer 112, the second semiconductor layer 122, the second semiconductor wafer 121′and the dressing layer 200. In these layers of the semiconductor structure 100″, the dressing layer 200 is the last layer that the grinding tool 300 contacts. As a result, even if the grinding tool 300 is deformed after grinding the first semiconductor wafer 111, the first semiconductor layer 112, the second semiconductor layer 122 and the second semiconductor wafer 121′, it may still be dressed (or shaped) by the dressing layer 200. As illustrated in FIG. 5B, the dressed (or shaped) grinding tool 300 has a flat appearance. For example, the dressed grinding tool 300 has a width W_{z}, and the widths W_{z} at a number of positions in X-axis are substantially equal (if not dressed, the difference of the width W_{z} of the grinding tool at a number of the positions in X-axis will be increased).

In another embodiment, at the grinding point G1, the tangential direction D1 of the rotation of the semiconductor structure 100″ and the tangential direction D2 of the rotation of the grinding tool 300 may be in the same direction (for example, the grinding tool 300 of FIG. 5C rotate around −X axis). In this example, when the grinding tool 300 rotates, the grinding tool 300 sequentially grinds the dressing layer 200, the second semiconductor wafer 121′, the second semiconductor layer 122, the first semiconductor layer 112 and the first semiconductor wafer 111. In these the layers of the semiconductor structure 100″, the dressing layer 200 is the first layer that the grinding tool 300 contacts. As a result, the grinding tool 300 may be dressed by the dressing layer 200 first, and then the dressed grinding tool 300 may grind the second semiconductor wafer 121′, the second semiconductor layer 122, the first semiconductor layer 112 and the first semiconductor wafer 111.

As described above, the grinding tool 300 will deform when cutting the material of the semiconductor structure. Through the dressing layer 200, the appearance of the grinding tool 300 may be correctly adjusted (dressed). The embodiment of the present invention does not limit the order of the deformation and the dressing of the grinding tool 300. In an embodiment, the grinding tool 300 may be deformed first and then dressed, and so on. In another embodiment, the grinding tool 300 may be dressed first and then deformed, and so on. In addition, in the present embodiment, grinding the edge area of the semiconductor structure 100″ and dressing the grinding tool 300 may be performed in the same grinding process. Compared with the conventional grinding method for a semiconductor wafer, the wafer grinding method for the semiconductor wafer according to the embodiment of the present invention does not require suspending the grinding operation and disassembling the grinding tool in order to dress the tool, and also does not need an additional dressing board.

As illustrated in FIG. 5D, when the platform 10 is rotated by 360 degrees, the entire edge area of the semiconductor structure 100″ is removed, but a portion of the thickness of the semiconductor structure 100″ is retain.

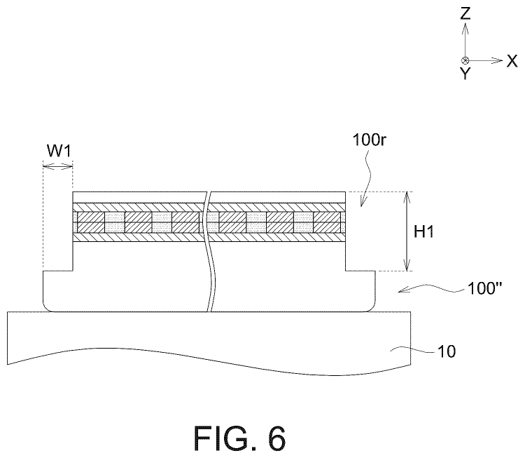

In step S150, referring to FIG. 6, FIG. 6 illustrates a schematic diagram of the dressing layer 200 on the semiconductor structure 100″ in FIG. 5D being removed. After the entire edge region of the semiconductor structure 100″ is removed, the dressing layer 200 on the semiconductor structure 100″ may be removed by using at least one of grinding, CMP, and etching. So far, the grinding operation of one set of semiconductor structures is completed.

Since there is no need to pause (or stop) the grinding operation and disassemble the grinding tool, after completing the grinding of one set of semiconductor structures, the grinding operation of the next set of semiconductor structure 100″ may be performed immediately. In other words, there is no need to pause (or stop) the grinding operation and disassemble the grinding tool between the grinding operations of two consecutive sets of the semiconductor structures 100″, and also the additional sharpening plate is not required.

As illustrated in FIG. 6, after grinding is completed, the semiconductor structure 100″ forms a grinding recess 100r. The grinding recess 100r has a grinding depth H1 and a grinding width W1, wherein the grinding depth H1 range between, for example, 250 μm and 350 μm, for example, 300 μm, and the grinding width W1 range between, for example, 2.5 millimeters (mm) and 3 mm, for example, 2.8 mm. In addition, due to the grinding tool 300 being dressed at the same time during the grinding process, a grinding surface 100s of the grinding recess 100r of the semiconductor structure 100″ is relatively smooth (compared to the conventional grinding process in which the grinding tool 300 is not dressed).

In summary, the embodiment of the present invention proposes a grinding method for a semiconductor structure. During the grinding process, the grinding tool is simultaneously dressed, so there is no need to pause (or stop) the grinding operation and disassemble the grinding tool. As a result, after completing the grinding of one set of semiconductor structure, the grinding operation of the next set of semiconductor structure may be immediately performed, and it may improve the grinding efficiency and increase the production capacity.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A grinding method for a semiconductor structure, comprising:
forming a dressing layer on the semiconductor structure; and
grinding the dressing layer and the semiconductor structure by a grinding tool.

2. The grinding method according to claim 1, wherein step of grinding the dressing layer and the semiconductor structure by the grinding tool comprising:
sequentially grinding the dressing layer and the semiconductor structure by the grinding tool.

3. The grinding method according to claim 1, wherein step of grinding the dressing layer and the semiconductor structure by the grinding tool comprising:
sequentially grinding the semiconductor structure and the dressing layer by the grinding tool.

4. The grinding method according to claim 1, wherein in forming the dressing layer on the semiconductor structure, the dressing layer is the outermost layer of the semiconductor structure.

5. The grinding method according to claim 1, wherein the dressing layer has Mohs hardness equal to or greater than 8.

6. The grinding method according to claim 1, wherein the dressing layer has a thickness ranging between 1 μm and 4 μm.

7. The grinding method according to claim 1, further comprising:
forming a first semiconductor layer on a first semiconductor wafer;
forming a second semiconductor layer on a second semiconductor wafer;
connecting the first semiconductor layer with the second semiconductor layer, wherein the first semiconductor layer and the second semiconductor layer are located between the first semiconductor wafer and the second semiconductor wafer;
thinning the second semiconductor wafer;
in forming the dressing layer on the semiconductor structure, the dressing layer is formed on the thinned second semiconductor wafer.

8. The grinding method according to claim 7, wherein in step of grinding the dressing layer and the semiconductor structure by the grinding tool, the grinding tool sequentially grinds the dressing layer and the thinned second semiconductor wafer.

9. The grinding method according to claim 7, wherein in step of grinding the dressing layer and the semiconductor structure by the grinding tool, the grinding tool sequentially grinds the thinned second semiconductor wafer and the dressing layer.

10. The grinding method according to claim 1, wherein after step of grinding the dressing layer and the semiconductor structure by the grinding tool, the grinding method further comprises:
removing the dressing layer.
